(19) United States
(12) Patent Application Publication
(10) Pub. No.: US 2009/0227100 A1
(43) Pub. Date: Sep. 10, 2009

(54) Method for fabricating semiconductor device

(75) Inventors: Tomomi Yamanobe, Ibaraki (JP); Toru Yoshie, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/379,931

(22) Filed: Mar. 4, 2009

(30) Foreign Application Priority Data
Mar. 5, 2008 (JP) 2008-055010

(51) Int. Cl. H01L 21/04

(52) U.S. Cl. 438/586; 257/E21.061; 257/E21.054

(57) ABSTRACT

A method for fabricating a semiconductor device includes the steps of forming an oxide film on a silicon carbide substrate; forming a gate electrode layer on the oxide film thereafter to pattern the gate electrode layer so as to form a gate electrode, comprising: and performing a thermal treatment to the gate electrode layer or the gate electrode in a mixed gas atmosphere of an oxidized gas and an inert gas.

### CROSS REFERENCE TO RELATED APPLICATION

This application claims the priority of Application No. 2008-055010, filed Mar. 5, 2008 in Japan, the subject matter of which is incorporated herein by reference.

### TECHNICAL FIELD OF THE INVENTION

The present invention relates to a method for fabricating a semiconductor device, and especially relates to a method for fabricating a semiconductor device using a silicon carbide substrate.

### BACKGROUND OF THE INVENTION

A semiconductor device using silicon carbide (SiC) crystal has such characteristics as a higher withstand voltage and a higher temperature operation compared with those of the prior art semiconductor device using Si crystal. Carbon atoms are contained in the SiC crystal, whereby the distance between the atoms is reduced to provide stronger coupling, and therefore, the size of the band gap of a semiconductor is increased twice or more. As a result, withstand voltage is increased to more than twice electric field, and the semiconductor characteristics are maintained even at a high temperature.

As a method for forming an oxide film on an SiC substrate, there is proposed a technique of heat-treating a substrate in an oxidizing atmosphere such as dry oxidation using O₂ or the like and wet oxidation using H₂O or the like (for example, see Japanese Patent Application Laid-Open No. 2007-201343).

However, especially when the oxide film is formed on a 3C—SiC substrate, an interface level and a fixed charge formed on the interface between the SiC substrate and the oxide film have been a problem.

Meanwhile, although a 4H—SiC substrate has optimum oxidation conditions different depending on the surface direction to be treated, the dry oxidation, Ar post-annealing, and H₂ annealing, which are performed at about 1300° C., and N₂O oxidation and other treatments at 1350° C. are effective on the Si surface. The wet oxidation at about 1000° C. is effective on the C surface.

When the above conditions are evaluated on the 3C—SiC substrate, it has characteristics approximating those of the C surface of the 4H—SiC substrate. The fixed charge is very large in the dry oxidation, and thus, the wet oxidation is effective.

In general, a gate electrode is formed of, for example, polysilicon on the oxide film, and thereafter, a thermal treatment is applied to the gate electrode so that the gate electrode is activated. However, due to the thermal treatment in the activation of the gate electrode, carbon segregates (is piled up) at the interface between the SiC substrate and a gate oxide film. The segregated carbon causes the increase of the interface level between the SiC substrate and the gate oxide film, that is, the generation of a positive fixed charge, and therefore, the absolute value of a flat-band voltage increases. Consequently, a threshold value of a semiconductor device is shifted to the negative side. As described above, even when the oxide film (gate oxide film) is formed by the wet oxidation, the negative shift occurs. When the amount of the negative shift of the threshold value is small, a correction can be performed so that the threshold value is shifted to a positive side by injection of phosphorous or the like; however, when the shift amount is large, this method cannot be used.

Thus, a current is applied to a semiconductor device even in a state that the gate voltage is not applied, and thus a so-called normally-off device cannot be fabricated.

### OBJECTS OF THE INVENTION

Accordingly, an object of the present invention is to provide a method for fabricating a semiconductor device which, even if a thermal treatment is performed for activating a gate electrode layer or a gate electrode, can realize the prevention of negative shift of a threshold value.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a method for fabricating a semiconductor device includes the steps of: forming an oxide film on a silicon carbide substrate; forming a gate electrode layer on the oxide film thereafter to pattern the gate electrode layer so as to form a gate electrode, comprising: and performing a thermal treatment to the gate electrode layer or the gate electrode in a mixed gas atmosphere of an oxidized gas and an inert gas.

The present invention can provide a method for fabricating a semiconductor device which, even if a thermal treatment is performed for activating a gate electrode layer or a gate electrode, can realize the prevention of negative shift of a threshold value.

In the method for fabricating a semiconductor device, the following operations and advantages will be provided.

In general, for the purpose of activating a gate electrode, the gate electrode is heat-treated. However, due to this thermal treatment, carbon atoms in an oxide film segregate at the interface between an SiC substrate and the oxide film. The carbon atoms are causative of the exhibition of behaviors of a positive fixed charge to increase the interface level so as to increase the flat-band voltage on a negative side. Consequently, a threshold value substantially shifts to the negative side, leading to the deterioration in the switching performance of the semiconductor device.

According to the present invention, since a gate electrode layer or a gate electrode is heat-treated using mixed gas composed of oxidized gas and inert gas, the carbon atoms segregating at the interface can be caused to disappear as carbon dioxide gas such as CO and CO₂.

Therefore, since the fixed charge and the interface level of the interface between the SiC substrate and the oxide film can be reduced, the absolute value of the flat-band voltage can be reduced. Namely, the negative shift of the threshold value is prevented, whereby the switching performance is substantially enhanced.

Further, the mixed gas in the present invention contains inert gas, so that the oxidation of the gate electrode can be prevented.

Moreover, the gate electrode layer is patterned to form the gate electrode, and thereafter, when the gate electrode is heat-treated in an oxidizing atmosphere, the damage of the edge portion of the gate electrode is recovered by reoxidation, thereby improving a breakdown voltage yield of the semiconductor device.

### BRIEF DESCRIPTION OF THE DRAWINGS

FIGS. 1A to 1D are process sectional views showing a process of forming a diffusion layer on an SiC substrate and thereafter to form a gate electrode in a method for fabricating a semiconductor device according to a first embodiment of the present invention;

FIG. 1E is a process sectional view showing a process of forming an interlayer insulation film and a contact hole in the method for fabricating a semiconductor device according to the first embodiment of the present invention;

FIGS. 2A to 2D are process sectional views showing a process of forming a diffusion layer on an SiC substrate and thereafter to form a gate electrode layer in a method for fabricating a semiconductor device according to a second embodiment of the present invention.

FIGS. 2E and 2F are process sectional views showing a process of forming a gate electrode and thereafter to form an interlayer insulation film and a contact hole in the method for fabricating a semiconductor device according to the second embodiment of the present invention.

FIG. 3 is a view showing a result of evaluation of C-V characteristics of a semiconductor device fabricated by the method for fabricating a semiconductor device of the present invention and the prior art fabricating method.

FIG. 4 is a table showing the result of evaluation of the C-V characteristics of the semiconductor device fabricated by the method for fabricating a semiconductor device of the present invention and the prior art fabricating method.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

Hereinafter, an SiC substrate used in a method for fabricating a semiconductor device of the present invention and the method for fabricating a semiconductor device will be described with reference to the drawings. The drawings are merely intended to schematically show shape, size and positional relation of the respective components to such a degree that the present invention can be understood, and thus are not intended to limit the present invention to the examples shown in the drawings. Although the specific materials, conditions, and numerical conditions or the like might be used in the following description, they are merely one preferred example. Thus, the present invention is by no means limited to them. Further, although an SiC substrate in the following embodiments has an N-type conductivity, a p-type SiC substrate may be used. The same holds for a diffusion layer.

### (SiC Substrate)

A semiconductor device fabricated by a method for fabricating a semiconductor device of the present invention uses an SiC substrate in view of high withstand voltage and high temperature operation. Examples of SiC include, for example, 2H—SiC, 3C—SiC, 4H—SiC, 6H—SiC, 8H—SiC, 10H—SiC, and 15R—SiC. They are represented by the Ramsdell notation. The first figures represent a number of unit layers of Si—C included in one period in a stacked direction (c-axis direction) and the alphabets C, H, and R following the figures respectively represent cubical crystal, hexagonal crystal, and rhombohedron. 4H—SiC, 6H—SiC, and 15R—SiC are produced at a high temperature of not less than 2000° C., and 3C—SiC can be produced at a low temperature of not more than 1800° C. 3C—SiC contains electrons with the highest running speed, in crystal, of all the above SiC (the saturation electron speed is 2.7 times as large as Si) and has a crystal structure (cubical crystal) similar to the conventional Si. Thus, a miniaturized device with high speed and high efficiency can be fabricated. In addition, since 3C—SiC can be produced at a low temperature, a 3C—SiC substrate is preferably used.

Further, the 3C—SiC substrate using Si as the substrate can be fabricated by a heteroepitaxial growth using a CVD method, and therefore, the diameter of the substrate can be easily increased, so that the cost of fabricating the substrate can be further reduced compared with other methods.

### First Embodiment

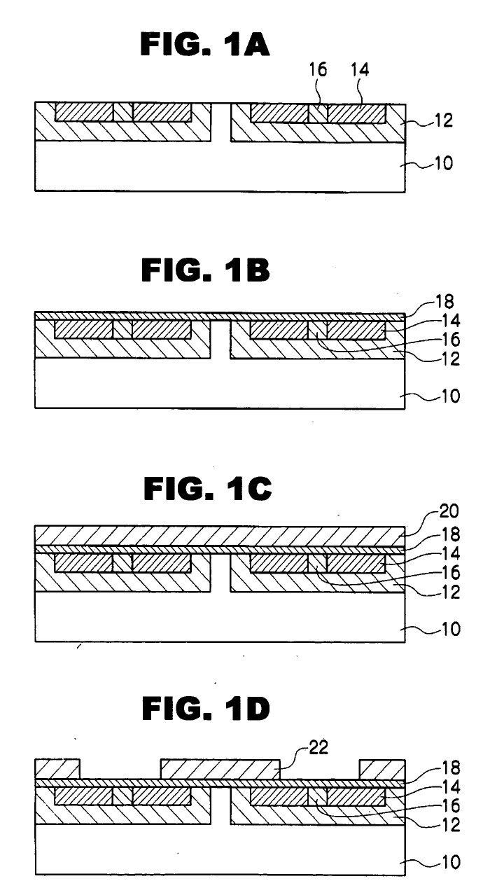

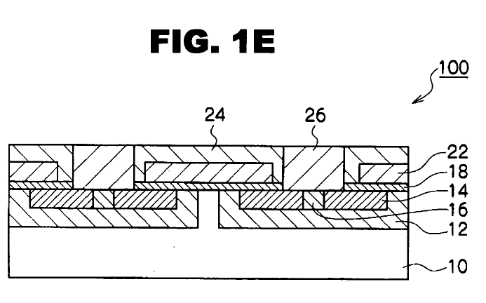

A method for fabricating a semiconductor device of a first embodiment of the present invention will be described in detail along FIGS. 1A to 1E.

First, as shown in FIG. 1A, various impurities are injected into a surface layer region of an N-type SiC substrate 10 doped with nitrogen, and a P-type diffusion layer 12, N+ diffusion layer 14, and a P+ diffusion layer 16 are formed. For example, Al ion is injected in the P-type diffusion layer 12 and the P+ diffusion layer 16, and phosphorous is injected in the N+ diffusion layer 14 (a source portion of MOSFET) by, for example, the conventional ion implantation method. Thereafter, the impurities are inactivated, and, at the same time, the crystallinity of the substrate is recovered, for example, for a processing time of several minutes to about 60 minutes at a temperature of about 1500 to 1700° C. in an Ar atmosphere or in a vacuum of not more than 1×10⁻⁵ Pa.

A gate oxide film 18 is then formed on the surface of the SiC substrate 10 as shown in FIG. 1B. In the formation of the gate oxide film 18 (oxide film), it is preferable that the SiC substrate 10, which includes the diffusion layers 12, 14, and 16 formed in the surface layer region, is formed by thermal oxidation.

The conditions of the thermal oxidation are not limited as long as the thermal oxidation is performed in the oxidizing atmosphere; however, in view of the prevention of the segregation of the carbon atoms, the gate oxide film 18 is preferably formed, in a mixed gas atmosphere of H₂ and O₂, at a temperature of about 1100 to 1200° C. for a processing time of about 30 minutes as the holding temperature and the holding time of the thermal oxidation. When the gate oxide film 18 is formed in the mixed gas atmosphere, that is, a wet atmosphere, the segregation of the carbon atoms in the gate oxide film 18 can be prevented. The thermal oxidation is preferably performed in the mixed gas also during rising and falling temperature because the segregation of the carbon atoms can be further prevented.

The mixing ratio between H₂ and O₂ (H₂:O₂) in the mixed gas is preferably about 1:2 to 1:100. If the mixing ratio is less than 1:2, explosion may occur. Meanwhile, if the mixing ratio is more than 1:100, an excessive large amount of O₂ causes the state to approach a dry atmosphere. Therefore, the carbon atoms in the gate oxide film segregate to cause the increase of the fixed charge and the interface level, whereby the flat-band voltage shifts to the negative side, and therefore, the threshold value of the semiconductor device may substantially shift to the negative side.

Next, as shown in FIG. 1C, a gate electrode layer 20 containing phosphorous is formed. In the formation of the gate electrode Layer 20, for example, SiH₄ gas and PH₄ gas are supplied at a ratio of about 10:1, and the formation is performed at 500 to 600° C. If the resistance of the gate electrode layer 20 is required to be reduced, WSi of about 100 to 300 nm may be formed on the gate electrode layer 20.

Thereafter, as shown in FIG. 1D, a gate electrode 22 is formed by known photolithography and etching techniques.

The thermal treatment is performed for activating the gate electrode 22 formed as above. As an atmosphere gas used in the thermal treatment, a mixed gas composed of oxidized gas and inert gas is used. The oxidized gas and the inert gas may be previously mixed as the mixed gas to be introduced into the treatment apparatus, or may be separately introduced in the treatment apparatus.

For the mixing ratio of the mixed gas in the present invention, the content of the oxidized gas in the mixed gas is preferably in the range of not less than 5 volume % and not more than 50 volume %, relative to the total volume of the mixed gas. When the content of the oxidized gas is in this range, as described above, the flat-band voltage is reduced to prevent the oxidation of the gate electrode 22. Therefore, it is preferable in that a removal process using dilute hydrofluoric acid or the like is not required. The content of the oxidized gas in the mixed gas is particularly preferably in the range of not less than 10 volume % and not more than 50 volume %. Within the range, the prevention of the shift of the threshold value and the prevention of the oxidation of the gate electrode are easily realized as the advantages of the invention. As described above, even if the gate electrode 22 has a structure in which WSi is stacked on polysilicon, the oxidation of WSi can be prevented.

The oxidized gas of the present invention is preferably selected from a group consisting of O₂, N₂O, NO₂, and H₂O. The carbon atoms segregating near the interface between the SiC substrate 10 and the gate oxide film 18 can be removed by using the selected oxidized gas.

The inert gas of the present invention is not limited as long as it prevents the gate electrode 22 from oxidizing; however, in view of versatility, the inert gas is preferably, for example, Ar and/or N₂.

Examples of the gate electrode layer 20 include polysilicon, WSi, TiSi, NiSi, CoSi, and the like, and at least two or more of them may be stacked. Especially when polysilicon is used, the polysilicon is crystallized by thermal treatment, whereby the gate electrode layer 20 can be inactivated.

In the present invention, the gate electrode 22 is preferably heat-treated at a temperature of not less than 750° C. and not more than 900° C. If the thermal treatment temperature is less than 750° C., the gate electrode 22 is not activated, whereas if the thermal treatment temperature is more than 900° C., the gate electrode 22 is oxidized, and in addition, a large amount of carbon atoms segregate, leading to the substantial negative shift of the threshold value. The thermal treatment temperature for further development of the effect is preferably not less than 750° C. and not more than 800° C. The thermal treatment temperature represents a thermal treatment holding temperature. The holding time at this thermal treatment temperature is preferably not less than 10 minutes and not more than 30 minutes. If the holding time is less than 10 minutes, the gate electrode 22 is not activated, whereas if the holding time is more than 30 minutes, the gate electrode 22 is oxidized, and a large amount of the carbon atoms segregate.

As a more preferable mode, when the gate electrode layer 20 or the gate electrode 22 is heat-treated, the oxidized gas is O₂ or H₂O, the inert gas is Ar or N₂, the content of the oxidized gas is not less than 10 volume % and not more than 50 volume % relative to the mixed gas composed of the oxidized gas and the inert gas, the thermal treatment temperature is not less than 750° C. and not more than 900° C., and the holding time is not less than 10 minutes and not more than 30 minutes.

The thermal treatment for activating the gate electrode 22 may be applied to the gate electrode 22 after photolithography and etching as described above, or may be applied to the gate electrode layer 20 before photolithography and etching. Even if the gate electrode is activated either before or after photolithography and etching, the carbon atoms segregating at the interface between the SiC substrate and the gate oxide film can be removed by oxygen in the oxidizing atmosphere.

Finally, as shown in FIG. 1E, the exposed gate oxide film is removed by etching, and the interlayer insulating film 24 is formed. A contact hole 26 formed of, for example, Al and Cu and a wiring (not shown) are then formed, so that the semiconductor device is fabricated.

### Second Embodiment

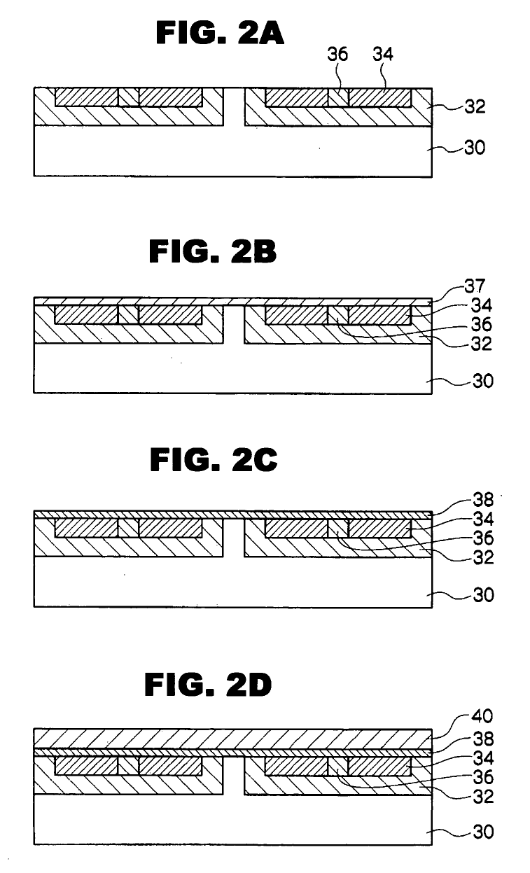

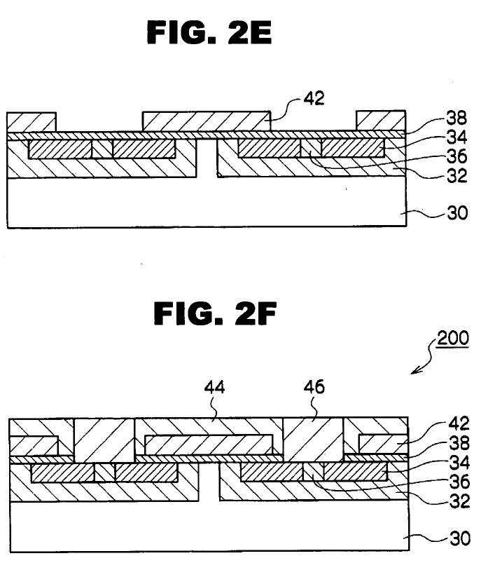

A method for fabricating a semiconductor device of the second embodiment of the present invention will be described in detail along FIGS. 2A to 2F.

First, as shown in FIG. 2A, a P-type diffusion layer 32, N+ diffusion layer 34, and P+ diffusion layer 36 are formed in a surface layer region of an SiC substrate 30, as in FIG. 1A.

Thereafter, as shown in FIG. 2B, an amorphous silicon layer 37 is formed on the SiC substrate 30. The film formation is performed at a temperature of not less than 500° C. and not more than 520° C. in an SiH₄ atmosphere or an SiH₂Cl₂ atmosphere. If the temperature is less than 500° C., the growth speed is slow, whereas the temperature is more than 520° C., polysilicon is formed. The film thickness of the amorphous silicon layer 37 is about ⅓ to ½ of a desired gate oxide film in view of no oxidation of the SiC substrate.

Next, as shown in FIG. 2C, a gate oxide film 38 is formed by thermal oxidation after the formation of the amorphous silicon layer 37. The thermal oxidation of the present embodiment is different from the thermal oxidation of the gate oxide film 18 in the first embodiment only in that the thermal treatment temperature is not less than 750° C. and not more than 900° C.

The gate oxide film 38 is preferably formed at not less than 500° C. and not more than 900° C. by a chemical vapor deposition (CVD) method. Namely, the film formation temperature of the present invention includes the film formation temperature of the amorphous silicon layer 37 and the thermal treatment temperature in the thermal oxidation as described above.

Finally, as in the process shown in FIGS. 1C, 1D, and 1E, a gate electrode layer 40 is formed as shown in FIGS. 2D, 2E, and 2F, and thereafter, a gate electrode 42 is formed by photolithography and etching. An interlayer insulating film 44 and a contact hole 46 are then formed, and thus the semiconductor device is fabricated.

As described above, in the method for fabricating a semiconductor device according to the second embodiment of the present invention, not the SiC substrate 30, but the amorphous silicon layer 37 is oxidized as an oxidation source for the gate oxide film 38, and the thermal treatment is performed at a temperature of a level short of oxidizing the SiC substrate. Thus, the gate oxide film 38 which is free from the influence of the carbon atoms in the SiC substrate 30 and has the reduced fixed voltage and the reduced interface level can be obtained.

Thereafter, since the gate electrode 42 is activated at a temperature of not less than 750° C. and not more than 900° C. in the oxidizing atmosphere as in the first embodiment, the carbon atoms do not segregate near the interface between the SiC substrate 30 and the gate oxide film 38, and thus a favorable gate oxide film 38 can be formed. Further, since the CVD film excellent in the step-covering performance is oxidized to from the gate oxide film 38, the defects on the SiC substrate 30 can be prevented, and in addition, the deterioration in the gate oxide film withstand voltage due to a step or the like can be prevented.

### Third Embodiment

In a method for fabricating a semiconductor device according to a third embodiment of the present invention, the gate oxide film is directly formed on an SiC substrate by the CVD method, instead of the thermal oxidation of the amorphous silicon layer in the method for fabricating a semiconductor device in the second embodiment.

Specifically, for example, the gate oxide film is formed, under low pressure, at a temperature of not less than 600° C. and not more than 900° C. in a mixed gas atmosphere of tetra ethyl ortho silicate (TEOS) and oxygen.

As the mixed gas, SiH₄ or Si₂H₆ may be used instead of TEOS. Further, N₂O, NO₂, or H₂O may be used instead of oxygen.

If the temperature in the film formation is not less than 900° C., it is not preferable because the carbon atoms in the SiC substrate excessively segregate. Meanwhile, if the temperature is not more than 600° C., it is not preferable because the decomposition of an Si raw material does not progress.

As described in the second embodiment, the gate oxide film is formed by the CVD method, and therefore can have an excellent step-covering performance, so that the deterioration in the gate oxide film withstand voltage due to a step or the like can be prevented. Further, since it is unnecessary to provide an additional process for oxidation, the fabrication process and time can be reduced.

A semiconductor device was fabricated by the method for fabricating a semiconductor device of the present invention, and the C-V characteristics and the oxidation of the gate electrode were evaluated.

### EXAMPLE 1

In Example 1, a semiconductor device was fabricated according to the method for fabricating a semiconductor device described in the first embodiment. The detail will be described hereinafter.

### Fabrication of Semiconductor Device

First, nitrogen atoms of 1×10¹⁶/cm³ were doped into a 3C—SiC substrate to provide an N-type substrate. Next, the 3C—SiC substrate was thermally oxidized for 25 minutes of the processing time at a temperature of 1170° C. and the rate of rising and falling temperature of 30° C./min. in an H₂O atmosphere (wet atmosphere), and thus a gate oxide film was formed. SiH₄ gas and PH₄ gas were then flown into a chamber, and a polysilicon layer of 400 nm was formed at 550° C. Thereafter, a thermal treatment was performed for 20 minutes at 800° C. in an atmosphere containing oxygen of 10% (N₂:O₂=500 scm: scm) to activate a gate electrode, and, thus, to form a gate electrode pattern by photolithography and etching, whereby an MOS capacitor was fabricated.

### Evaluation of Semiconductor Device

### (C-V Characteristics)

In the evaluation of the C-V characteristics, using an LCR meter (model number: 4274A) from Agilent Technologies, a hysteresis, obtained from a gate voltage and a capacitance (μF/cm²) normalized by a maximum capacitance value, was measured at a measured frequency of 100 kHz and a measured step voltage of 0.2 V, and the negative shift of the hysteresis and the slope were evaluated. Further, a flat-band voltage Vfb was calculated based on the evaluation result of the C-V characteristics.

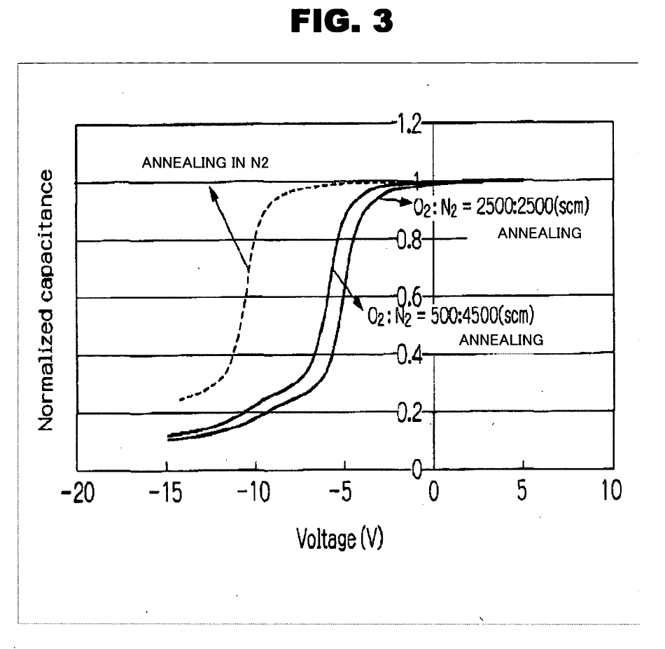

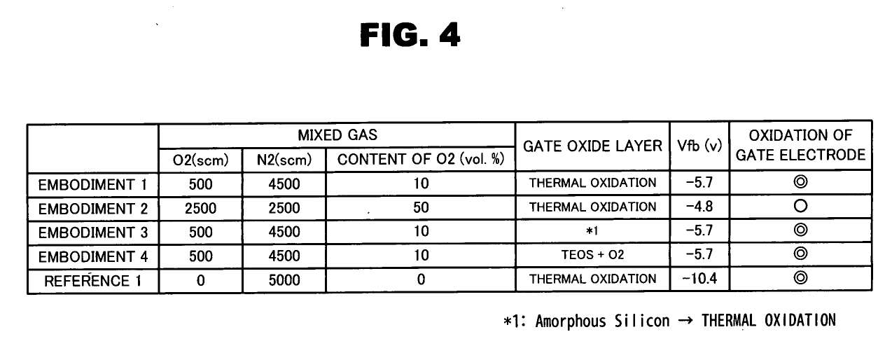

The evaluation result is shown in FIGS. 3 and 4.

### Oxidation of Gate Electrode

The degree of oxidation of the surface of a gate electrode was evaluated in a stepwise manner as follows:

(double circle): CV curves can be obtained at most positions where the evaluation of the C-V characteristics is performed, and the influence of the oxidation of the gate electrode surface can be ignored;

(single circle): the CV curves cannot be obtained at many positions in the evaluation of the C-V characteristics, and there are many positions affected by the oxidation of the gate electrode surface. An oxide film may be removed; and

(triangle): a thick oxide film is formed on the gate electrode surface, and the oxide film should be removed to evaluate the C-V characteristics.

The result is shown in FIG. 4.

### EXAMPLE 2

In Example 2, a semiconductor device was fabricated according to the method for fabricating a semiconductor device described in the first embodiment.

Specifically, the MOS capacitor was fabricated in a similar manner to Embodiment 1; however, the gate electrode was activated in the thermal treatment atmosphere in which N₂:O₂=2500 scm 2500 scm.

The result is shown in FIGS. 3 and 4.

### EXAMPLE 3

In Example 3, a semiconductor device was fabricated according to the method for fabricating a semiconductor device described in the second embodiment.

Specifically, the MOS capacitor was fabricated in a similar manner to Embodiment 1; however, the gate oxide film was formed as follows, instead of the thermal oxidation in Embodiment 1.

First, an amorphous silicon layer was formed at 510° C. in an SiH₄ atmosphere by the CVD method. Next, the amorphous silicon layer was thermally oxidized for 30 minutes of the processing time at 850° C. and the rate of rising and falling temperature of 30° C./min. in an H₂O atmosphere (wet atmosphere), and thus a gate oxide film was formed.

The C-V characteristics of the MOS capacitor fabricated as above were evaluated. The same evaluation result as Embodiment 1 could be obtained.

### EXAMPLE 4

In Example 4, a semiconductor device was fabricated according to the method for fabricating a semiconductor device described in the third embodiment.

Specifically, the MOS capacitor was fabricated in a similar manner to Embodiment 1; however, a gate oxide film was formed as follows, instead of the thermal oxidation of amorphous silicon in Embodiment 3.

An SiC substrate formed with a diffusion layer was treated by the CVD method for 60 minutes at 700° C. and 1 Pa in a mixed gas with a ratio of TEOS:O₂=2:1, and thus the gate oxide film was formed.

The C-V characteristics of the MOS capacitor fabricated as above were evaluated. The same evaluation result as Embodiment 1 could be obtained.

### (Reference 1)

In a reference 1, the MOS capacitor was fabricated in a similar manner to Embodiment 1; however, a gate electrode was heat-treated in N₂ gas instead of the mixed gas in Embodiment 1. The C-V characteristics of the MOS capacitor fabricated by this method were evaluated.

The result is shown in FIGS. 3 and 4.

As seen in FIG. 3, in an MOS capacitor semiconductor device fabricated by the method for fabricating a semiconductor device of the present invention, the negative shift of the C-V characteristics is reduced. Further, as shown in FIG. 4, it is found that the oxidation of the gate electrode does not progress in spite of small Vfb of the gate electrode.

What is claimed is:

1. A method for fabricating a semiconductor device comprising:
forming an oxide film on a silicon carbide substrate;
forming a gate electrode layer on the oxide film thereafter to pattern the gate electrode layer so as to form a gate electrode, comprising: and
performing a thermal treatment to the gate electrode layer or the gate electrode in a mixed gas atmosphere of an oxidized gas and an inert gas.

2. The method for fabricating a semiconductor device according to claim 1, wherein
the mixed gas contains the oxidized gas of not less than 5 volume % and not more than 50 volume %.

3. The method for fabricating a semiconductor device according to claim 1, wherein
the oxidized gas is selected from a group consisting of O₂, N₂O, NO₂, and H₂O.

4. The method for fabricating a semiconductor device according to claim 1, wherein
the inert gas is Ar and/or N₂.

5. The method for fabricating a semiconductor device according to claim 1, wherein
the thermal treatment in the mixed gas is performed at a temperature of not less than 750° C. and not more than 900° C.

6. The method for fabricating a semiconductor device according to claim 1, wherein
the silicon carbide substrate is thermally oxidized so as to form the oxide film.

7. The method for fabricating a semiconductor device according to claim 1, wherein
the oxide film is formed by a chemical vapor deposition method at a temperature of not less than 500° C. and not more than 900° C.

8. The method for fabricating a semiconductor device according to claim 7, wherein
an amorphous silicon layer is formed before the formation of the oxide film to be thermally oxidized so as to form the oxide film.

9. The method for fabricating a semiconductor device according to claim 7, wherein
the oxide film is formed in a mixed gas atmosphere of tetraethoxysilane (TEOS) and oxygen.

10. The method for fabricating a semiconductor device according to claim 1, wherein
the silicon carbide substrate is a cubic silicon carbide substrate.
